(19) United States
(12) Patent Application Publication
(10) Pub. No.: US 2025/0038550 A1
(43) Pub. Date: Jan. 30, 2025

(54) BATTERY DISCONNECT UNIT AND A DRIVE SYSTEM

(71) Applicant: Robert Bosch GmbH, Stuttgart (DE)

(72) Inventors: Roman Marx, Moensheim (DE); Markus Schmitt, Tamm (DE)

(21) Appl. No.: 18/782,369

(22) Filed: Jul. 24, 2024

(30) Foreign Application Priority Data
Jul. 24, 2023 (DE) 10 2023 207 005.7

(51) Int. Cl. H02J 7/00; H01M 10/42; H01M 10/613; H01M 10/625; H01M 10/653; H01M 10/6551; H01M 10/6554; H01M 10/6569; H01M 10/667; H01M 50/325

(52) U.S. Cl. CPC H02J 7/0031; H01M 10/425; H01M 10/613; H01M 10/625; H01M 10/653; H01M 10/6551; H01M 10/6554; H01M 10/6569; H01M 10/667; H01M 50/325; H01M 2220/20

(57) ABSTRACT

A battery disconnect unit for separating a battery arrangement from at least one consumer of a drive system includes a cooling device having a media-tight housing. The housing includes a base plate and a cooling plate arranged opposite the base plate. The housing forms an internal volume at least partially filled with a dielectric fluid. The battery disconnect unit further includes at least one component of a power electronics system arranged on the base plate of the cooling device via at least one ceramic substrate. The at least one component of the power electronics system is covered with the dielectric fluid in the internal volume of the housing of the cooling device.

### BACKGROUND

The invention relates to a battery disconnect unit and a drive system.

According to the prior art, a battery disconnect unit (BDU) is used to switch the battery of an electric vehicle on and off, depending on the operating status. In this context, the three BDU configurations specified are usually used:
1. fuse and relay
2. pyro fuse and relay
3. fuse, pyro fuse, and relay.

When using a combination of a relay and a circuit using a SiC-based semiconductor on AMB components for a BDU, active cooling of these components is necessary because these semiconductors achieve high heat flux densities and the associated temperatures due to their compact design. AMB stands for Active Metal Brazing, and the component is a ceramic substrate that is connected directly to a base plate via a solder connection. Cooling is, e.g., achieved a cooling plate, through which a coolant flows. According to the prior art, a cooling plate made of aluminum sheets in a brazing process can be used in this case. Depending on the requirements with regard to the currents being switched and the power losses in the form of heat, these cooling plates can be equipped with an additional water fin (internal insert) to increase the cooling capacity. In this case, the AMB components are soldered onto the cooling plate in order to achieve an optimum thermal transition from the AMB building block to the cooling plate via the water fin into the cooling fluid.

This not only places high demands on the choice of internal inserts, but also on the volumetric flow of the cooling fluid and its maximum permissible temperature. The aim is to cool the semiconductors effectively and to ensure that the temperature distribution of the individual chips with respect to one another is as homogeneous as possible.

As a result of these requirements, cooling plates featuring a relatively high pressure loss are used in this type of cooling concept. In combination with the required high volumetric flow, this leads to additional cooling systems with high pump capacities. These not only consume a lot of energy, but also lead to higher costs and vehicle weight due to their dimensions.

The chips are usually encapsulated to prevent leakage currents and short circuits between the closely spaced electrical conductors. Additional components, e.g. a limiting frame and the casting compound, are required in this case, which incurs additional costs.

### SUMMARY

The disadvantages specified hereinabove are remedied by a battery disconnect unit and by a drive system having the features of the disclosure. Further features and details of the invention arise from the description and the drawings. Features and details that are described in connection with the battery disconnect unit according to the invention naturally also apply in connection with the drive system according to the invention, and vice versa, so that, with regard to the disclosure, reference is or can always be made to the individual aspects of the invention reciprocally.

A first aspect of the invention is a battery disconnect unit for separating a battery arrangement from at least one consumer of a drive system, said battery disconnect unit comprising a cooling device having a media-tight housing, whereby the housing comprises a base plate and a cooling plate arranged opposite the base plate, and whereby the housing forms an internal volume, whereby a part of the internal volume is filled with a dielectric fluid. The battery disconnect unit further comprises at least one component, in particular a plurality of components, of a power electronics means, whereby the at least one component of the power electronics means is arranged on the base plate of the cooling device via at least one ceramic substrate. The at least one component of the power electronics means is covered with the dielectric fluid in the internal volume of the housing of the cooling device.

The at least one component of the power electronics means, for example a SiC chip, is arranged on the at least one ceramic substrate. A large number of components can in this case also be arranged on a ceramic substrate. It is also conceivable that multiple ceramic substrates are provided, each comprising at least one component or multiple components.

The at least one component or the large number of components in the power electronics means generate a high heat flux density or heat in a very small space during operation. This heat is partially distributed in a conductive manner via the ceramic substrate and the base plate.

Due to the overlapping of the at least one component of the power electronics means comprising the dielectric fluid, the heat is transferred to the dielectric fluid, meaning that the dielectric fluid can initially absorb the heat of the at least one component directly. Given that the dielectric fluid absorbs the heat, its temperature rises until reaching the boiling point at the respective boiling temperature and boiling pressure of the fluid. Under these conditions, the dielectric fluid undergoes a phase change. The boiling of the dielectric fluid results in high turbulence in the area of the boiling bubbles, which leads to a very high heat transfer coefficient. This is also referred to as evaporative cooling and is a very efficient form of heat transport.

In addition to the high turbulence generated during boiling and the high energy transfer due to the phase change, a further factor regards efficient cooling. Specifically, a significant increase in the surface area of the heat source (i.e., from the at least one component of the power electronics means to the cooling plate) can be used. This increase in surface area results in significantly lower heat flux densities at the cooling plate. As a result, there is no need to use highly efficient cooling plates. The cooling plates can be dimensioned with a larger cross-sectional flow area, or lower volumetric flows can be set, resulting in lower pressure losses. The option also exists of using the existing cooling plates by thermally connecting the BDU to the corresponding surface.

In the context of the invention, it may be advantageous for the internal volume to be filled with the dielectric fluid to between 1% and 100%, preferably between 5% and 70%, more preferably between 10% and 50%.

The internal volume can be completely filled with the dielectric fluid, which ensures that the at least one component of the power electronics means is covered with the dielectric fluid, even when the entire drive system is moving.

However, one covering is sufficient for cooling the at least one component. Accordingly, the internal volume can be filled to at least 1%, depending on the size of the volume or the dimensions of the base plate. However, a filling from 5% to 70%, or 10% to 50%, is preferred.

As a result, the cooling can be performed optimally by the evaporate cooling, and any boiling losses can be compensated for.

Within the scope of the invention, it is also possible for a copper layer, in particular a cold-sprayed copper layer, to be provided between the base plate and the ceramic substrate.

The use of a copper layer to connect the ceramic substrate to the base plate is particularly advantageous because both a thermal and a mechanical connection can be achieved quickly and efficiently. The ceramic substrate comprising the at least one component is connected in a bonded to the copper layer on the base plate in a soldering process. As a result, a very effective thermal transition from the ceramic substrate to the base plate is achieved.

The partial dissipation of heat via the copper layer and the base plate can be further increased if the base plate is made of a material with effective thermal conductivity, e.g. aluminum.

Within the scope of the invention, a pressure equalization device can be provided provided in the housing of the cooling device in order to equalize the pressure in the internal volume.

This enables pressure equalization in the event of an increase in pressure in the internal volume due to an increase in volume of the dielectric fluid as a result of heating. The use of a pressure equalization device, e.g. a diaphragm pressure equalization vessel, can already be advantageous when at least 70%, but in any case 100%, of the internal volume is filled with the dielectric fluid.

It is also conceivable that, when the internal volume is filled with the dielectric liquid up to a maximum of 99.9%, the remainder of the internal volume is filled with an auxiliary medium, in particular a compressible medium.

By using an auxiliary medium, pressure equalization can be performed when the volume of the dielectric fluid changes.

Compressible media such as air, nitrogen, and inert gas have proven to be particularly advantageous as auxiliary media.

It is also conceivable that the cooling plate of the cooling device comprises at least two, preferably a plurality of, cooling fins on an inner surface facing the internal volume and/or an outer surface facing away from the internal volume.

By means of the cooling fins on the inner surface facing the internal volume or the outer surface facing away from the internal volume, an additional increase in surface area can be generated, via which the heat can be dissipated. At the same time, it is conceivable that the cooling plate be additionally cooled via
the outer surface comprising at least two cooling fins in order to cool the dielectric such that as much heat as possible can be dissipated from the components of the power electronics means.

Within the scope of the invention, it is optionally possible for the outside of the cooling plate of the cooling device to be connectable to a cooling unit of the consumer, or a cooling unit of the battery arrangement, or for liquid cooling or air cooling to be provided.

By connecting to an external cooling unit or a liquid cooling system, the cooling plate can be additionally cooled efficiently so that the rising, boiling dielectric fluid can be cooled quickly in order to be available again as condensate for cooling the at least one component.

Within the scope of the invention, it can also be provided that the dielectric fluid has a viscosity from 0.5 mPas to 1000 mPas, preferably 0.5 mPas to 500 mPas, more preferably 0.5 mPas to 100 mPas.

The dielectric fluid is a fluid that is not electrically conductive. Dielectric fluids can also have an increased viscosity in the range of between 1 mPas and 1000 mPas. The viscosity can in this case change briefly due to the heating of the dielectric fluid. At the same time, it should be ensured that a certain viscosity be present in order to be able to generate a uniform flow. Dielectric fluids with a viscosity from 50-700 mPas are preferred because these values can ensure a uniform flow and effective absorption of the heat flux density.

In relation to the present invention, it is conceivable that the dielectric fluid has a heat capacity from 0.8 to 4 KJ/kgK, preferably from 1.0 to 2.5 KJ/kgK, more preferably from 2 to 3 KJ/kgK.

Dielectric fluids with an increased heat capacity can absorb more heat and transport it away. Accordingly, dielectric fluids with a heat capacity from 0.8 to 4 KJ/kgK ensure that the heat generated is dissipated quickly and efficiently.

It is also conceivable that a battery interface for electrical connection to the battery arrangement is provided, and that a consumer interface for electrical connection to the consumer is provided.

The battery interface and the consumer interface are particularly advantageous for simple connection to a battery unit, or to the consumer of a drive system. These consumer interfaces, or rather the battery interface, can in this case be provided for the control and regulation of the battery disconnect unit, or rather the battery unit, and the consumer by means of the battery disconnect unit. However, a data-communicating consumer interface or a battery interface that transmits certain data (e.g., the temperature or pressure in the internal volume) to a control unit is also conceivable.

The second aspect of the invention is a drive system according to the invention comprising a battery arrangement, a consumer, and a battery disconnect unit according to the first aspect, whereby the battery arrangement and the battery disconnect unit are electronically connected to each other via the battery interface, and whereby the consumer and the battery disconnect unit are connected to each other via the consumer interface.

The drive system comprises the battery disconnect unit described hereinabove and the advantages thereof.

Advantages which have been described in detail with respect to the battery disconnect unit according to the first aspect of the invention apply equally to the drive system according to the second aspect of the invention.

Further advantages, features, and details of the invention follow from the description hereinafter, in which several exemplary embodiments of the invention are described in detail with reference to the drawings. In this context, the features mentioned in the claims and in the description can each be essential to the invention, individually or in any combination desired. The invention is illustrated in the following drawings:

### BRIEF DESCRIPTION OF THE DRAWINGS

FIG. 1 is a schematic representation of a battery disconnect unit according to the invention,

FIG. 2 is a schematic representation of a drive system according to the invention.

### DETAILED DESCRIPTION

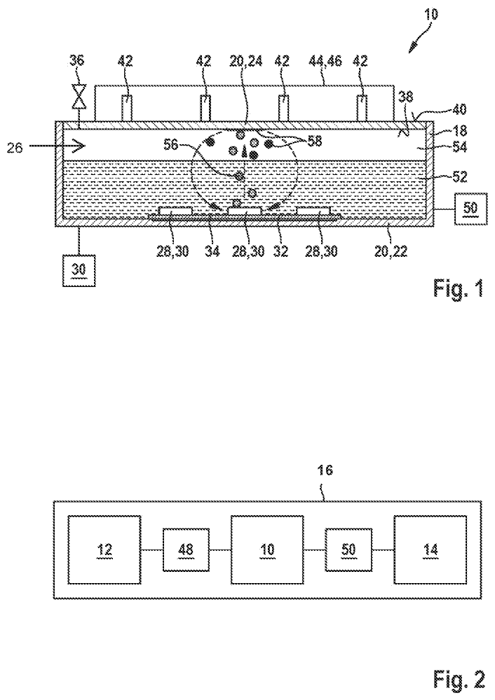

FIG. 1 shows a battery disconnect unit 10 for disconnecting a battery arrangement 12 from at least one consumer 14 of a drive system 16. The battery disconnect unit 10 comprises a cooling device 18 having a media-tight housing 20 and at least one component 28, in particular a plurality of components 28, of a power electronics means 30. The housing 20 of the cooling device 18 comprises a base plate 22 and a cooling plate 24 arranged opposite the base plate 22, and forms an internal volume 26, whereby a part of the internal volume 26 is filled with a dielectric fluid 52. The at least one component 28 of the power electronics means 30 is arranged on the base plate 22 of the cooling device 18 via or by means of at least one ceramic substrate 32. In order to increase the surface area for heat dissipation, the at least one component 28 of the power electronics means 30 is covered with the dielectric fluid 52 in the internal volume 26 of the housing 20 of the cooling device 18.

In the illustrated exemplary embodiment, the internal volume 26 is approximately 70% filled with the dielectric fluid 52. However, it is conceivable that the internal volume 26 is filled from 1% to 100% with the dielectric fluid 52.

During operation of the battery disconnect unit 10, the components 28 of the power electronics means 30 become warm and generates a high level of heat flux density or heat. This heat is transferred to the dielectric fluid 52, which begins to boil and undergoes a phase change. As a result, the convective bubbles 56 that form rise and are cooled when they reach the cooling plate 24 before falling back into the dielectric fluid 52 as condensate 58. This creates the turbulence required for optimum heat transfer. At the same time, the condensate 58, i.e. the condensed dielectric fluid 52, has released thermal energy to the cooling plate 24, so that the at least one component 28 is cooled in turn.

To connect the ceramic substrate 32 to the at least one component 28 of the power electronics means 30, a copper layer 34, in particular a cold-sprayed copper layer 34, is provided between the base plate 22 and the ceramic substrate 32. This enables a secure thermal and mechanical connection to the base plate 22.

To increase safety in the event of increasing pressure due to the increase in volume of the dielectric fluid, a pressure equalization device 36 in the form of a diaphragm pressure equalization vessel is provided in the internal volume 26 in the housing 20 of the cooling device 18.

Since the internal volume 26 is not completely filled, but only about 70%, the remainder of the internal volume 26 is filled with an auxiliary medium 54. Compressible media are preferably used for this purpose. In this case, the auxiliary medium 54 is air.

Cooling fins 42 can be provided to cool the cooling plate 24, i.e., to provide the dew point of the dielectric fluid as quickly as possible. In the exemplary embodiment according to FIG. 1, multiple cooling fins 42 are provided on an outer surface 40 facing away from the internal volume 26. Additionally or alternatively, the at least two cooling fins 42 can also be provided on an inner surface 38 facing the internal volume 26.

In order to cool the cooling plate 24 from the outside, the latter provided with a liquid cooling system 46. In further embodiments (not shown in this case), the cooling plate 24 of the battery disconnect unit 10 can be connectable to an external cooling unit 44 such that the cooling units 44 already provided for the consumer 14 or the battery arrangement 12 can be used.

The dielectric fluid 52 used in this case has a viscosity from 0.5 mPas 20° C. to 1000 mPas 20° C. and a heat capacity from 0.8 to 4 KJ/kgK.

Furthermore, a battery interface 48 for electrical connection to the battery arrangement 12 and a consumer interface 50 for electrical connection to the consumer 14 are provided in the exemplary embodiment according to FIG. 1.

FIG. 2 shows a drive system 16 comprising a battery arrangement 12, a consumer 14, and a battery disconnect unit 10, as shown in FIG. 1. The battery arrangement 12 and the battery disconnect unit 10 are electronically connected to each other via the battery interface 48. At the same time, the consumer 14 and the battery disconnect unit 10 are connected to each other via the consumer interface 50.

1. A battery disconnect unit (10) for disconnecting a battery arrangement (12) from at least one consumer (14) of a drive system (16), said battery disconnect unit comprising:
a cooling device (18) having a media-tight housing (20), wherein the housing (20) comprises a base plate (22) and a cooling plate (24) arranged opposite the base plate (22), and wherein the housing (20) forms an internal volume (26), wherein a part of the internal volume (26) is filled with a dielectric fluid (52),
at least one component (28) of power electronics means (30),
wherein the at least one component (28) of the power electronics means (30) is arranged on the base plate (22) of the cooling device (18) via at least one ceramic substrate (32), wherein the at least one component (28) of the power electronics means (30) is covered with the dielectric fluid (52) in the internal volume (26) of the housing (20) of the cooling device (18).

2. The battery disconnect unit (10) according to claim 1, wherein the internal volume (26) is filled from 1% to 100% with the dielectric fluid (52).

3. The battery disconnect unit (10) according to claim 1, wherein a copper layer (34) is provided between the base plate (22) and the ceramic substrate (32).

4. The battery disconnect unit (10) according to claim 1, wherein a pressure equalizing device (36) is provided in the housing (20) of the cooling device (18) to equalize pressure in the internal volume (26).

5. The battery disconnect unit (10) according to claim 1, wherein, when the internal volume (26) is filled with the dielectric liquid by at most 99.9%, a remainder of the internal volume (26) is filled with an auxiliary medium (54).

6. The battery disconnect unit (10) according to claim 1, wherein the cooling plate (24) of the cooling device (18) comprises, on an inner surface (38) facing the internal volume (26) and/or an outer surface (40) facing away from the internal volume (26), at least two cooling fins (42).

7. The battery disconnect unit (10) according to claim 1, wherein an outside of the cooling plate (24) of the cooling device (18) can be connected to a cooling unit (44) of the consumer (14) or a cooling unit (44) of the battery arrangement (12), or wherein liquid cooling (46) or air cooling (46) is provided.

8. The battery disconnect unit (10) according to claim 1, wherein the dielectric fluid (52) has a viscosity from 0.5 mPas (20° C.) to 1000 mPas (20° C.).

9. The battery disconnect unit (10) according to claim 1, wherein the dielectric fluid (52) has a heat capacity from 0.8 to 4 KJ/kgK.

10. The battery disconnect unit (10) according to claim 1, wherein a battery interface (48) is provided for electrical connection to the battery arrangement (12), and a consumer interface (50) is provided for electrical connection to the consumer (14).

11. A drive system (16) comprising a battery arrangement (12), a consumer (14), and a battery disconnect unit (10) according to claim 1, wherein the battery arrangement (12) and the battery disconnect unit (10) are electronically connected to each other via the battery interface (48), and wherein the consumer (14) and the battery disconnect unit (10) are connected to each other via the consumer interface (50).

12. The battery disconnect unit (10) according to claim 1, wherein the power electronics means (30) includes a plurality of components (28).

13. The battery disconnect unit (10) according to claim 2, wherein the internal volume (26) is filled from 15% to 70% with the dielectric fluid (52).

14. The battery disconnect unit (10) according to claim 13, wherein the internal volume (26) is filled from 10 to 50% with the dielectric fluid (52).

15. The battery disconnect unit (10) according to claim 3, wherein the copper layer (34) is a cold-sprayed copper layer (34).

16. The battery disconnect unit (10) according to claim 5, wherein the auxiliary medium (54) is a compressible medium.

17. The battery disconnect unit (10) according to claim 8, wherein the dielectric fluid (52) has a viscosity from 0.5 mPas (20° C.) to 500 mPas (20° C.).

18. The battery disconnect unit (10) according to claim 17, wherein the dielectric fluid (52) has a viscosity from 0.5 mPas (20° C.) to 100 mPas (20° C.).

19. The battery disconnect unit (10) according to claim 9, wherein the dielectric fluid (52) has a heat capacity from 1.0 to 2.5 KJ/kgK.

20. The battery disconnect unit (10) according to claim 19, wherein the dielectric fluid (52) has a heat capacity from 2 to 3 KJ/kgK.
